(19) United States
(12) Patent Application Publication
(10) Pub. No.: US 2008/0094787 A1
(43) Pub. Date: Apr. 24, 2008

(54) Portable Electronic Device

(75) Inventor: Akifumi Kabeya, Singapore (SG)

Correspondence Address: DICKSTEIN SHAPIRO LLP, 1825 EYE STREET NW, Washington, DC, 20006-5403, US

(73) Assignee: OLYMPUS TECHNOLOGIES PTE LTD., SINGAPORE (SG)

(21) Appl. No.: 10/592,720

(22) PCT Filed: Feb. 28, 2005
(86) PCT No.: PCT/SG05/00058

§ 371 Date: Sep. 13, 2006

(30) Foreign Application Priority Data
Mar. 15, 2004 (SG) 200401460-1

(51) Int. Cl. H05K 7/06

(52) U.S. Cl. 361/681

(57) ABSTRACT

A portable electronic device is disclosed in which an LCD (140) and a PCB (130) of the device are mounted on to first and second opposed sides of an internal frame. The internal frame has a stiffness chosen to suppress the distortion of the LCD and vibration of the PCB (140) resulting from a shock. A battery (170) is mounted onto the PCB (140) such that the internal frame supports the LCD (140) on one side and the PCB (130) with the battery mounted on it on the opposite side.

### FIELD OF THE INVENTION

The present invention relates to the field of portable electronic devices more particularly to the shock-resistance of such devices,

### BACKGROUND OF THE INVENTION

With the miniaturisation of electronic components and the introduction of lightweight flat panel displays, portable electronic devices such as PDAs, cell phones and digital cameras continue to become more widespread as they shrink in size while incorporating additional features at the same time. However, one of the main problems facing the manufacturers of portable electronic devices is that being portable, the devices are prone to being dropped or otherwise knocked in use, with the resulting shock to the components being a major cause of damage to and failure of such portable electronic devices. Therefore, it is desirable that portable electronic devices have some degree of shock resistance so that they do not fail when dropped or knocked.

Generally, the working components (e.g. LCD, memory devices, battery) of a portable electronic device are contained within an external housing which serves as physical protection for the components. However, even with an external housing, it is a problem that failure of the components in the housing can still occur if the housing is subjected to a force, not only where the housing itself breaks, but also in some cases even if the housing remains intact

It is an object of the invention to provide a portable electronic device which alleviates this problem and/or provides the general public with a useful choice.

### SUMMARY OF THE INVENTION

According to the invention in a first aspect, there is provided a portable electronic device comprising: a housing; a frame internal of the housing; a printed circuit board and a display mounted on and supported by the frame, the frame having a stiffness and/or a spring constant higher than that of the circuit board or the display.

Preferably, the printed circuit board is mounted on a first side of the frame and the display is mounted on the second opposing side of the frame.

A battery which is preferably of flat or pancake-like dimensions may be mounted on the frame, preferably be being affixed to the printed circuit board. Where the battery has a plurality of sides of differing surface area, the side of largest surface area is preferably affixed to the printed circuit board.

The frame preferably forms a backbone for the components mounted thereon.

The frame may be formed from metal, preferably a magnesium alloy or may be formed from a non-metallic material such as Fibre Reinforced Plastic or Carbon Fibre Reinforced Plastic.

The display is preferably a liquid crystal display.

According to the invention in a second aspect, there is provided a portable electronic device comprising a housing; a printed circuit board and a battery disposed within the housing, wherein the battery is attached to the printed circuit board to provide support for the printed circuit board.

The invention of the second aspect preferably includes a frame, to which the circuit board is attached, the frame may be stiffer than the circuit board and the frame and battery may be attached to opposed sides of the circuit board.

In the described embodiment of the present invention, a frame internal to the housing of a portable electronic device is provided. The internal frame is of substantial stiffness and functions as a backbone which supports working components mounted on the frame, in particular a display and a pcb. This approach departs from conventional designs, where in order to minimise the size of the portable electronic device, the external housing is used as an exoskeletal structure providing most of the support for the device components and a mounting structure for fastening together the various components comprising the device.

### BRIEF DESCRIPTION OF THE DRAWINGS

An embodiment of the invention will now be described, by way of example, with reference to the accompanying drawings in which:

FIG. 1 is a cross-sectional view of an embodiment of the invention, being a personal data assistant (PDA) fitted with an internal frame;

FIG. 2 is an exploded three-dimensional view of the embodiment of FIG. 1.

### DETAILED DESCRIPTION OF THE PREFERRED EMBODIMENT OF THE INVENTION

Portable electronic device manufacturers have conventionally tried to improve device shock resistance by improving the properties of the external housing material. However, although the external housing shields the working components from direct impact, the inventors have found that shock pulses a rising from an impact are not fully absorbed or dissipated by the housing but get transmitted through to the components. This leads to a problem with external housing design. On the one hand it is desirable to have a more rigid housing to withstand shocks, but on the other hand, the more rigid the external housing is, the lesser the ability of the housing to absorb and damp shock load.

The inventors have recognised that shock load transmitted through a housing can contribute to the failure of portable electronic devices. In particular, the inventors have identified two additional failure modes arising from transmitted shock load. Firstly, the transmitted shock load can cause distortion of the housing, which distortion is transmitted to the working components in a portable electronic device. Since LCDs are generally brittle and exhibit very poor elastic limits, distortion can result in fracture or multi-hued distortion (called rain bowing) of the LCD. Secondly, the transmitted shock pulses can because vibration waves to be set up in the housing, which are transmitted to the components. PCBs are particularly vulnerable to vibration in view of the many soldered joints between components which can easily be dislodged resulting in failure.

The embodiment of the present invention addresses these additional modes of failure to provide another means of shock resistance other than an external housing

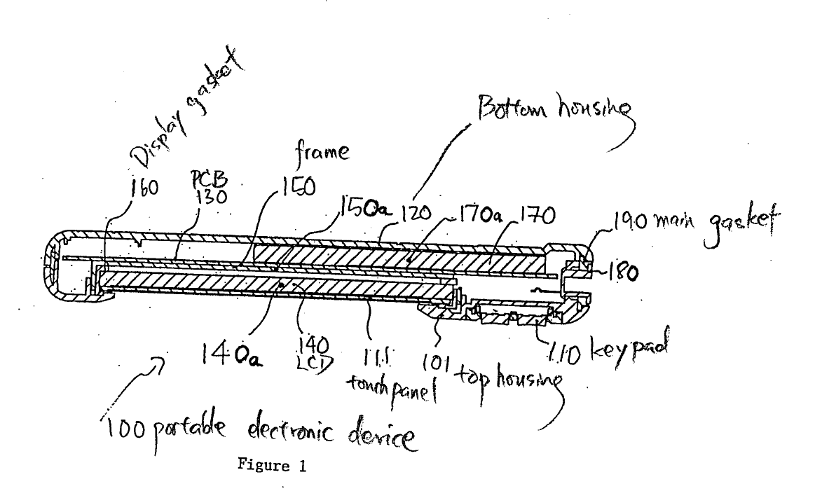

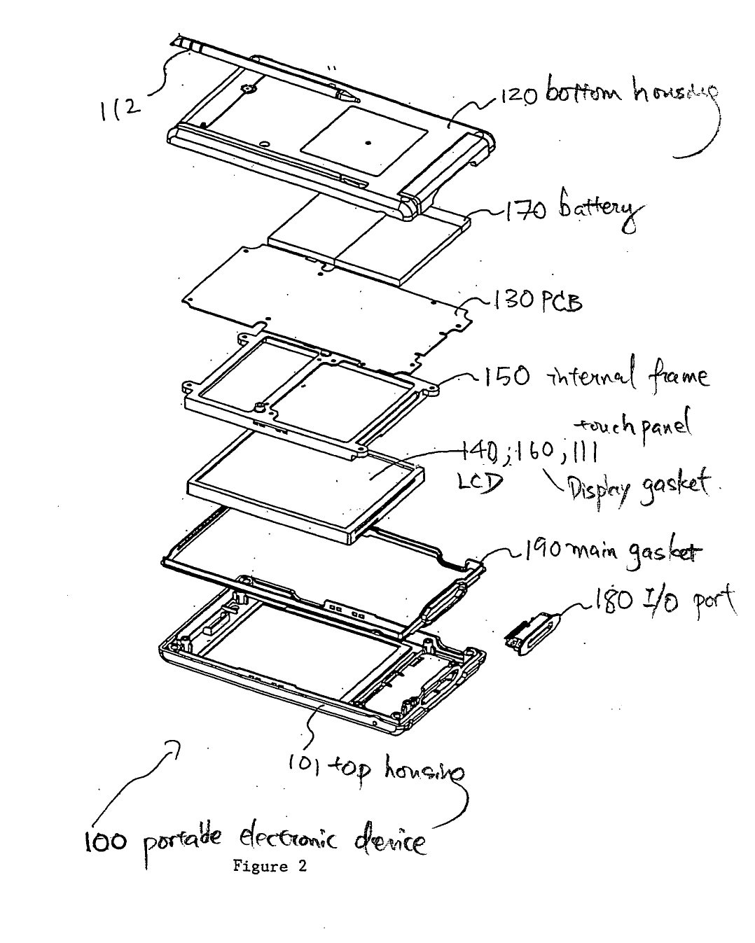

FIGS. 1 and 2 illustrate a portable electronic device 100 in accordance with one embodiment of the invention. In this embodiment a rigid internal frame 150 is provided. The frame has a peripheral oblong frame member and one cross-member both of ‘L’-shape cross-section and includes threaded openings to receive screws to allow attachment of components of the device. The internal frame 150 supports a LCD 140 and a PCB 130 which includes processing circuitry of the device and driving circuitry. The LCD and PCB are securely mounted onto the internal frame by screws or suchlike. In the preferred embodiment shown in FIGS. 1 and 2, the LCD and PCB are mounted on opposed sides of the frame. The internal frame serves as a “backbone” to the components to lower the likelihood of failure and therefore improve the shock resistance of the PDA by suppressing the distortion of the LCD and reducing the amplitude of vibration of the PCB during a shock event. In order to provide adequate support for the LCD and PCB during a shock, the internal frame has to be stiffer and/or have a higher spring constant than the components it is supporting. In general, the higher spring constant k the frame has, the better it's ability to suppress distortion of the LCD and resist vibration.

In one embodiment, the internal frame is made from a magnesium (Mg) alloy such as AZ91D, a commonly used magnesium alloy for thixotropic die casting, includes 9% of Al and 1% of Zn. which is relatively lightweight and has higher strength/stiffness. Other transition metal alloys such as Al and Ti may be used as can non-metals, e.g. FRP (Fibre Reinforced Plastic) or CFRP (Carbon Fibre Reinforced Plastic).

The stiffness required would also depend on the environment where the portable device is to be used. Generally industrial devices are subjected to more stringent standards and the portable devices designed for use in an industrial environment would have to survive higher shocks. Therefore, industrial portable electronic devices generally require stiffer internal frames.

The resulting combination of the PCB 130, internal frame 150 and LCD 140 gives rise to a unitary structure wherein the movements of the components are, essentially, synchronised. By making the movements of the components more predictable, it is easier for designers to model and optimise the shock response behaviour of the components, which in turn means designers can optimise and thus reduce) the size of the frame for a given shock resistance. The described embodiment also has the advantage of combining shock protection for several components on one structure. By eliminating the need to have separate shock protection structures for the LCD and the PCB, further miniaturisation of the whole device is facilitated.

As shown in FIGS. 1 and 2, the working components of the PDA are contained within an external protective housing comprising a top housing 101 and a bottom housing 120 which are sealed together through a main gasket 190. Three openings are provided on the top housing: one for viewing the LCD screen, one for housing the key pad 110 and one for receiving the 1/0 port 180. In one embodiment, the internal frame 150 (with the PCB 130 and LCD 140 mounted on opposed sides of the frame) is securely mounted onto the top housing 1 (e.g. by screws or other fastening means) to form a larger unitary structure. The touch panel 111 is applied to the LCD and enwrapped by the display gasket 160 together with the LCD integrally. In this embodiment, the display gasket is formed from rubber material and is chosen such that they help to dampen any shock by absorbing some of the shock energy arising from the impact and also to seal the water around the opening for LCD screen at the same time. This improves the shock absorption characteristics of the housing as a whole so that the shock transmitted to the internal components such as the LCD and circuit board can be reduced.

In a portable electronic device, the LCD and the battery are typically the main components that have a large volume and heavy weight. In conventional portable electronic devices, the battery is mounted next to the PCB or in a separate compartment. In one embodiment of the present invention, the strength and spring constant of the unitary structure comprising the PCB 3, internal frame 150 and LCD 140 is increased by attachment of a battery 170 to the PCB 130, preferably by adhesive. In this embodiment, the battery 170 is mounted onto the PCB 130 such that the internal frame 150 and battery 170 together sandwich and support the PCB. By mounting the battery on the PCB, the vibration and distortion of the PCB is limited not only by the internal frame which supports on one side but also the battery which is mounted on the other side.

Preferably the battery is of flat or pancake-like dimensions, with the face of the battery of largest surface area being attached to the PCB to provide support over as large a surface area of the PCB as possible.

One additional advantageous effect of connecting the LCD, battery, PCB and frame together in a unitary structure is that the structure will have a single identifiable centre of gravity. This allows the relative placement of the components to be chosen to position the centre of gravity relative to the housing to minimize the effects of shock. Generally having the centre of gravity of the unitary structure and the housing the same or similar will reduce the effects on the unitary structure of a shock applied to the housing.

The embodiment of the invention described is not to be construed as limitative. For example, although the figures illustrate the invention as applied to a PDA, the invention is also relevant to any other types of portable electronic devices having a display for example and without limitation to transmitting and/or receiving devices such as cell phones, optical devices such as digital cameras, measuring and sensing devices such as electronic cable finders and spirit levels, portable data processing devices such as computers and apparatus for processing sounds and/or images, such as portable dvd players or televisions.

The battery need not be mounted on the pcb can be disposed separately in the housing. The LCD and PCB can be mounted onto the same side of the internal frame, next to each other or with the LCD being mounted on the PCB in a sandwich arrangement.

1. A portable electronic device comprising: a housing; a frame internal of the housing; a printed circuit board and a display mounted on and supported by the frame, the frame having a stiffness and/or a spring constant higher than that of the circuit board or the display.

2. A portable electronic device as claimed in claim 1, wherein the printed circuit board is mounted on a first side of the frame and the display is mounted on the second opposing side of the frame.

3. A portable electronic device as claimed in claim 1, further comprising a battery mounted on the frame.

4. A portable electronic device as claimed in claim 3, wherein the battery is mounted onto the frame by being affixed to the printed circuit board.

5. A portable electronic device as claimed in claim 4, wherein the battery has a plurality of sides of differing surface area and the side of largest surface area is affixed to the printed circuit board.

6. A portable electronic device as claimed in claim 4 wherein the battery is of flat or pancake-like dimensions

7. A portable electronic device as claimed in claim 1 wherein the frame forms a backbone for the components mounted thereon.

8. A portable electronic device as claimed in claim 1 wherein the frame is formed from metal.

9. A portable electronic device as claimed in claim 8 wherein the metal is a magnesium alloy.

10. A portable electronic device as claimed in claim 1 wherein the frame is formed from a non-metallic material.

11. A portable electronic device as claimed in claim 10 wherein the frame is formed from Fibre Reinforced Plastic or Carbon Fibre Reinforced Plastic.

12. A portable electronic device as claimed in claim 1 wherein the display is a liquid crystal display.

13. A portable electronic device comprising a housing; a printed circuit board and a battery disposed within the housing, wherein the battery is attached to the printed circuit board to provide support for the printed circuit board.

14. A device as claimed in claim 13 further comprising a frame, to which the circuit board is attached.

15. A device as claimed in claim 14 wherein the frame and battery are attached to opposed sides of the circuit board.

16. A device as claimed in claim 14 wherein the frame is stiffer than the circuit board.
